(19) United States
(12) Patent Application Publication
(10) Pub. No.: US 2006/0202702 A1
(43) Pub. Date: Sep. 14, 2006

(54) Headset charging system with interchargeable charge devices

(75) Inventors: Soohyun Ham, San Francisco, CA (US); Jack A. Reynolds, Santa Cruz, CA (US)

Correspondence Address: PLANTRONICS, INC., 345 ENCINAL STREET, P.O. BOX 635, SANTA CRUZ, CA, 95060-0635, US

(73) Assignee: Plantronics, Inc., A DELAWARE CORPORATION, Santa Cruz, CA (US)

(21) Appl. No.: 11/351,489

(22) Filed: Feb. 9, 2006

Related U.S. Application Data
(60) Provisional application No. 60/660,254, filed on Mar. 9, 2005.

(51) Int. Cl. G01R 31/02

(52) U.S. Cl. 324/537; 324/538

(57) ABSTRACT

Headset pocket charging system with interchangeable charge devices are disclosed. The headset charging system generally includes a headset charger configured to be coupled to interchangeable charging devices and an interchangeable charging device configured to be removably coupled to the headset charger for charging the headset. Each interchangeable charging device may be a charge converter device for coupling to an AC or DC adapter or a battery charge device for containing at least one battery. The charging system may be part of a kit that includes a mobile telephone, the headset configured for use with the mobile telephone, AC or DC mobile telephone adapter, the interchangeable charging device being configured to be coupled to the mobile telephone adapter for charging the headset. The charging system may be adapted for use with other electronics components such as PDAs, cameras, and the like.

### CROSS REFERENCE TO RELATED APPLICATIONS

This application claims priority to U.S. Provisional Patent Application Ser. No. 60/660,254, filed on Mar. 9, 2005 entitled “Headset Charging System with Interchangeable Charge Devices,” which is incorporated herein by reference in its entirety.

### BACKGROUND OF THE INVENTION

1. Field of the Invention

The present invention relates generally to headsets for use in audio applications such as telecommunications and telephony. More specifically, headset pocket charging system with interchangeable charge devices are disclosed.

2. Description of Related Art

Communication headsets are used in numerous applications and are particularly effective for telephone operators, radio operators, aircraft personnel, and for any user for whom it is desirable to have hands free operation of communication systems. Accordingly, a wide variety of conventional headsets are available. For example, communication headsets may be adapted for use with corded and cordless conventional telephones, soft phones, cellular phones, and the like.

Communication headsets may be wired or wireless. Wireless headsets provide additional conveniences by providing further flexibility and freedom in movement for the user. Wireless headsets generally require electrical power to operate and may be rechargeable. For example, wireless headsets may be charged using an AC adapter or other charging mechanism provided by the original equipment manufacturer (OEM) of the wireless headset. The OEM may provide a docking station such as a desktop charger or other combined storage and charging mechanism to facilitate the charging of the wireless headset.

For further convenience, belt clip chargers are available to provide power for the headset and are an added convenience for users, particularly those who often travel away from the docking station. The belt clip charger facilitates storage and transport as well as charging of the headset. The belt clip charger may be clipped to the user's belt, for example, for storage and transport and for easy access. When the headset is to be charged, the belt clip charger may be removed from the user and plugged directly to an AC outlet, for example.

However, the headset and the base telephone, such as the cellular telephone, are often manufactured by different manufacturers and thus different chargers are generally required to be used to charge the base telephone and the headset. Such a configuration is bulky, inconvenient, and costly for the user.

### SUMMARY OF THE INVENTION

Headset pocket charging system with interchangeable charge devices are disclosed. It should be appreciated that the present invention can be implemented in numerous ways, including as a process, an apparatus, a system, a device, or a method. Several inventive embodiments of the present invention are described below.

The headset charging system generally includes a headset charger such as a headset charge pocket having internal electrical contacts configured to facilitate charging a headset in electrical communication with the headset charger, the headset charger being configured to be coupled to differently configured interchangeable charging devices, and at least one interchangeable charging device configured to be repeatedly coupled to and uncoupled from the headset charger and to facilitate charging the headset via a charge source such as an AC or DC adapter and/or a battery.

The at least one interchangeable charging device may be a charge converter device configured to be coupled to an AC or DC adapter. Alternatively or additionally, the at least one interchangeable charging device may be a battery charge device configured to contain at least one battery for charging the headset. Each battery may be a readily available consumer battery (rechargeable or non-rechargeable), such as alkaline, NiCad (Nickel Cadmium) and/or lithium batteries in various form factors such as AA or AAA form factors, for example. Each interchangeable charging device may in turn be removably coupled to another interchangeable charging device such as for storage and ease of transport. The headset charger may be configured to be directly coupled to a headset AC and/or DC adapter when the interchangeable charging device is uncoupled from the headset charger.

The charging system may be part of a kit that includes a mobile telephone, the headset configured for use with the mobile telephone, an AC and/or DC mobile telephone adapter for charging the mobile telephone, the interchangeable charging device being configured to be coupled to the mobile telephone adapter to facilitate charging of the headset. The charging system may be adapted for use with other electronics components such as PDAs, cameras, and the like.

These and other features and advantages of the present invention will be presented in more detail in the following detailed description and the accompanying figures which illustrate by way of example principles of the invention.

### BRIEF DESCRIPTION OF THE DRAWINGS

The present invention will be readily understood by the following detailed description in conjunction with the accompanying drawings, wherein like reference numerals designate like structural elements.

FIG. 1 is a schematic of a headset charge pocket of a headset pocket charging system for storing and charging a headset.

FIG. 2 is a perspective view of the headset charge pocket of FIG. 1.

FIG. 3 is a bottom view of the headset charge pocket of FIG. 1.

FIG. 4 is a perspective view of the headset charge pocket for charging the headset stored therein via an AC adapter connector of an illustrative AC adapter.

FIG. 5 is a perspective view of the headset charge pocket connected to an interchangeable charge converting device for charging the headset stored therein via an alternative AC adapter.

FIG. 6 is a perspective view of the headset charge pocket connected to an interchangeable battery charge device for charging the headset stored therein via at least one battery contained in the interchangeable battery charge device.

FIG. 7 is a perspective view of the headset stored in the headset charge pocket to which the interchangeable battery charge device containing the at least one battery and the interchangeable charge converting device are attached.

FIG. 8 is a perspective view of a kit including a container containing the headset charge pocket, the headset with interchangeable earbuds and the earloop, and various interchangeable charge devices.

FIG. 9 is a perspective view of another kit including a mobile phone, an AC and/or DC adapter for the mobile phone, a headset, and a headset charge pocket with one interchangeable charge device for use with the mobile phone AC or DC adapter.

### DESCRIPTION OF SPECIFIC EMBODIMENTS

Headset pocket charging system with interchangeable charge devices are disclosed. The following description is presented to enable any person skilled in the art to make and use the invention. Descriptions of specific embodiments and applications are provided only as examples and various modifications will be readily apparent to those skilled in the art. The general principles defined herein may be applied to other embodiments and applications without departing from the spirit and scope of the invention. Thus, the present invention is to be accorded the widest scope encompassing numerous alternatives, modifications and equivalents consistent with the principles and features disclosed herein. For purpose of clarity, details relating to technical material that is known in the technical fields related to the invention have not been described in detail so as not to unnecessarily obscure the present invention.

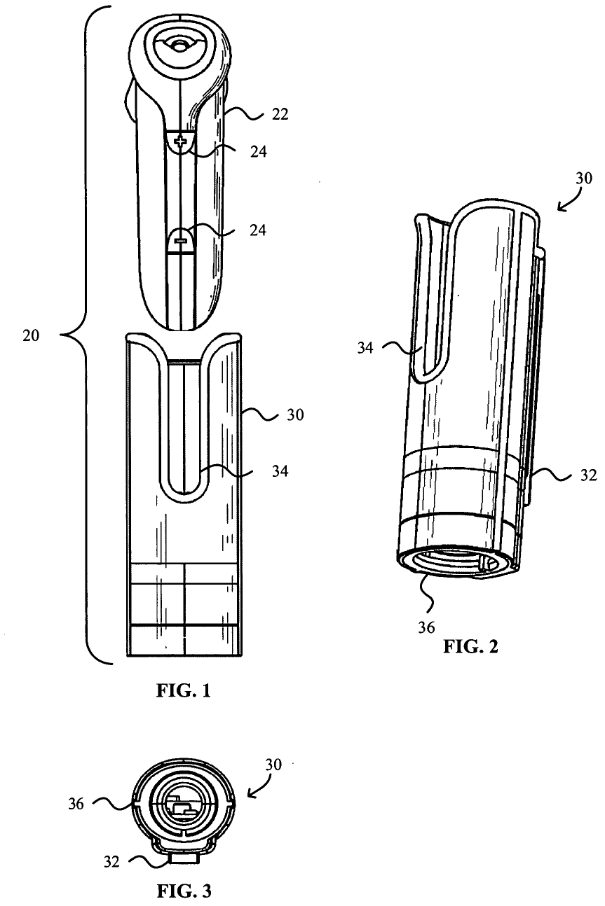

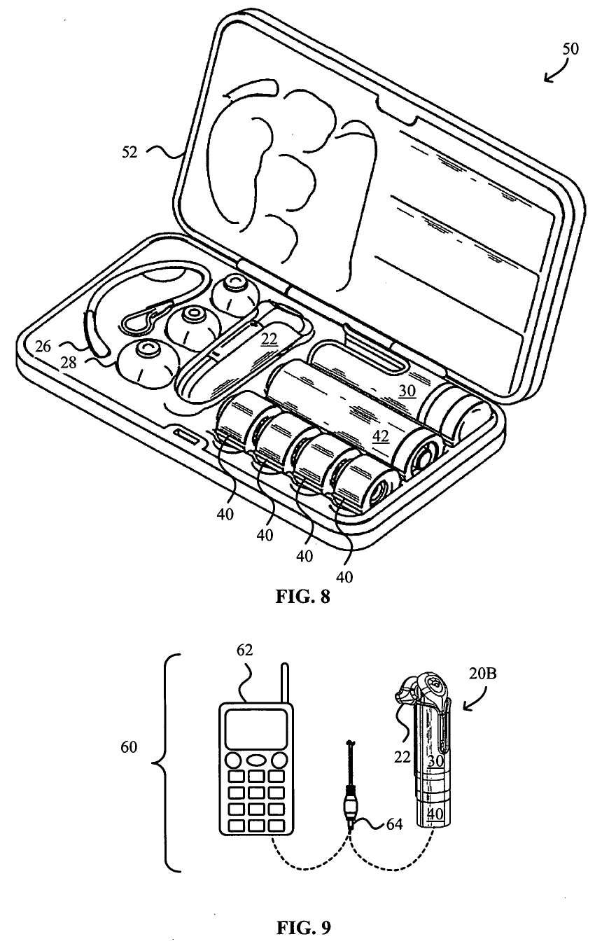

FIG. 1 is a schematic of a headset pocket charging system 20 including a headset charge pocket 30 for receiving a headset 22 therein for storage, transport and charging. The headset charge pocket 30 not only serves as a protective storage and carrying case for the headset 22 when it is not in use but also enables charging of the headset 22 via at least one of a set of interchangeable charge devices as will be described in more detail below. The illustrative headset shown and described herein is a monaural headset having a single audio receiver for placement near one ear. A monaural headset is often implemented with an earloop (as shown in FIG. 7) configured to fit around the ear to secure the receiver in place. It is to be understood that the headset charge pocket 30 may be configured to receive various other types, shapes and/or configurations of headsets and that the monaural headset 22 shown herein is merely one example of a headset suitable for use with the headset pocket charging system 20.

The headset charge pocket 30 is shown in more detail in the perspective and bottom views of FIGS. 2 and 3, respectively. As shown, the headset charge pocket 30 may provide a clip 32 or other attachment mechanism to enable the user to attach the headset charge pocket 30 along with its contents and attachments, if any, to the user's belt or pocket, for example, to enhance portability of the headset pocket charging system 20. The headset charge pocket 30 may also provide an opening 34, e.g., for aesthetic purposes, to accommodate the configuration of the headset 22, and/or to allow access to controls 24 (also shown in FIG. 1) and/or displays (not shown) such as a visual ring indicator or a caller ID display, provided on the headset 22. Optionally, a car or desk base adapter or cradle (not shown) may also be provided to further facilitate storage of the headset pocket charging system 20 and charging of the headset 22.

The headset charge pocket 30 supplies charging to the headset 22 via internal electrical contacts partially shown in FIG. 3. As shown in FIGS. 2 and 3, the bottom of the headset charge pocket 30 may be configured to directly be connected to a connector for an alternating current (“AC”) adapter or to receive an interchangeable charge device. In particular, the headset 22 may be charged by connecting a connector of an AC or direct current (“DC”) adapter directly to the headset charge pocket 30 and connecting the opposite end of the AC or DC adapter to an electrical source such as an AC outlet or a DC source such as an automobile's cigarette lighter. The headset 22 may also be charged using an AC or DC adapter that is not configured to be directly connected to the headset charge pocket 30 via the use of an appropriate interchangeable charge device. Specifically, the headset pocket charging system 20 may include various interchangeable charge devices that may be connected to the headset charge pocket 30. In one configuration, each interchangeable charge device may be attached to the charge pocket 30 via an attachment mechanism provided at the bottom of the headset charge pocket 30. For example, the bottom of the headset charge pocket 30 may be configured to receive an AC or DC adapter connector, a charge converter which in turn may be connected to an alternative AC or DC adapter, or a battery case for charging the headset stored in the headset charge pocket 30 via at least one battery contained in the battery case, for example. Each interchangeable charge device may be configured to receive another interchangeable charge device such that various interchangeable charge devices may be easily and conveniently stored and transported as a single unit, for example.

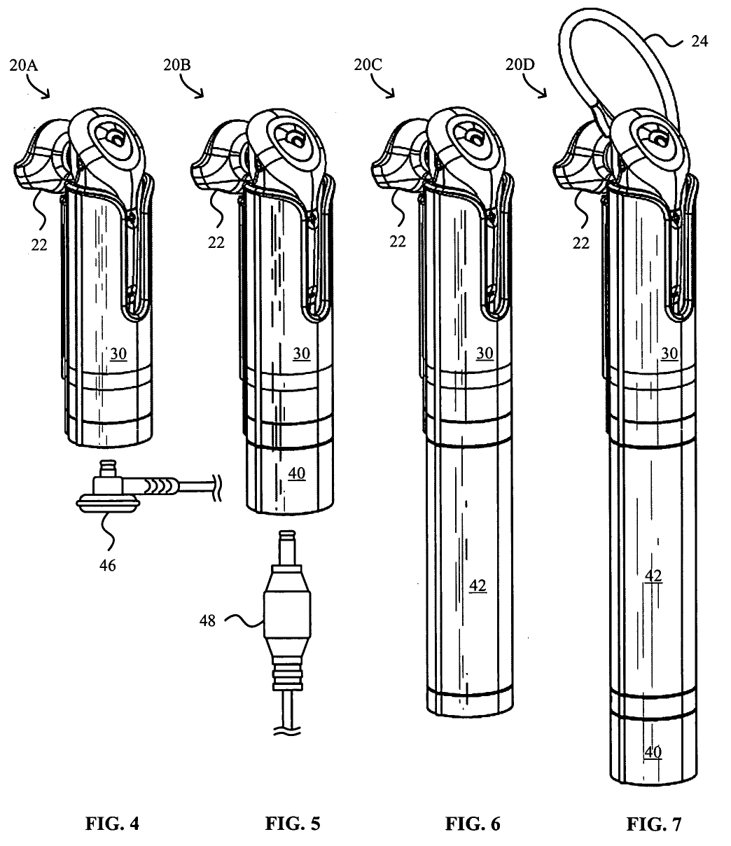

FIGS. 4-7 are perspective views of illustrative configurations for the headset pocket charging system 20A-20D, respectively. In particular, FIG. 4 is a perspective view of one configuration of the headset pocket charging system 20A in which the headset charge pocket 30 may charge the headset 22 stored therein via an AC adapter connector 46 of an illustrative AC adapter (not shown). In such a configuration, the headset charge pocket 30 is configured to directly receive the AC adapter connector 46 without the need for an interchangeable charge device to be attached thereto. Typically, such an AC adapter is provided by the manufacturer of the headset 22 and headset pocket charging system 20.

As noted, alternative mechanisms for charging the headset 22 via the headset charge pocket 30 may be provided by the headset pocket charging system 20. In particular, the headset pocket charging system 20 may be provided with one or more interchangeable charge devices to which the headset charge pocket 30 may be connected. For example, FIG. 5 is a perspective view of another configuration of the headset pocket charging system 20B in which the headset charge pocket 30 may be connected to an interchangeable charge converter device 40 for charging the headset 22 stored therein via an AC adapter connector 48 of an alternative AC adapter (not shown). The alternative AC adapter may be one that is provided with a cellular telephone or a personal digital assistant (PDA), for example. Generally, the headset charge pocket 30 is not configured to be connected directly to the alternative AC adapter and requires the use of the interchangeable charge converter device 40. Although one example of an interchangeable charge converting device 40 is shown and described herein, various other interchangeable charge converting devices 40 configured to be coupled to corresponding AC or DC adapters may be provided with the headset pocket charging system 20. For example, interchangeable charge converting devices 40 may be provided for various AC or DC adapters of varying voltages.

In addition to interchangeable charge converters 40 for use with various AC or DC adapters, the headset pocket charging system 20 may additionally or alternatively provide other interchangeable charge converters such as those for use with batteries such as readily available consumer batteries (rechargeable and/or non-rechargeable), such as Alkaline, NiCad or Lithium in AA or AAA form factors, for example, or various other suitable types of batteries. FIG. 6 is a perspective view of yet another configuration of the headset pocket charging system 20C in which the headset charge pocket 30 may be connected to an interchangeable battery charge device 42 for charging the headset 22 stored therein via one or more batteries contained in the battery charge device 42. Each battery can be easily replaced (and/or recharged if the battery is rechargeable) when drained.

With each of the interchangeable charge devices 40, 42 shown in FIGS. 5 and 6, the interchangeable charge devices 40, 42 and the headset charge pocket 30 are configured so that the interchangeable charge device can be easily attached to and detached from the headset charge pocket 30. In one embodiment, each interchangeable charge device 40, 42 may be snapped, twisted, screwed or otherwise removably attached to the bottom of the headset charge pocket 30 to allow the user to charge the headset 22 using various types of chargers such as various AC and/or DC chargers. For example, with the use of an appropriate charge device, the headset 22 from one manufacturer can be charged using a mobile phone charger from a different manufacturer, thereby eliminating the need for a user to carry a separate AC or DC adapter for the headset and/or eliminating the need for the headset manufacturer to provide an AC or DC adapter with the headset charging system 20.

Furthermore, when the headset 22 and headset charging system 20 are bundled with a particular mobile phone with a specific AC and/or DC adapter, the headset 22 and headset charging system 20 may be sold or otherwise provided only with charge converting devices compatible with the AC and/or DC adapters for the mobile phone. Such a provision thus eliminates the need to include a separate AC or DC adapter specific to the headset charging system 20, resulting in cost savings to the user as well as in fewer accessories to transport particular for the mobile user.

FIG. 7 is a perspective view of yet another configuration of the headset pocket charging system 20D in which the headset 22 (shown with an earloop 24 attached) is stored in the headset charge pocket 30 to which the interchangeable battery charge device 42 as well as the interchangeable charge converter device 40 are attached. Such a configuration 20D may be a configuration to facilitate ease of storage and transport without providing charging capabilities. Alternatively, the configuration 20D may provide for charging of the headset 22 using the battery charge device 42 and/or the corresponding AC or DC adapter via the charge converter device 40. As yet another alternative embodiment, the configuration 20D may provide for charging of at least one rechargeable battery contained in the battery charge device 42. It is noted that various other interchangeable charge devices may be provided and attached to the headset charge pocket 30 similar to the configuration 20D shown in FIG. 7.

As is evident, the headset 22 and the headset charging system 20 may be provided as a kit 50, as shown in the perspective view of FIG. 8. The kit 50 may include a container 52 for containing various components of the headset 22 and various components of the headset charging system 20. For example, the various components of the headset 22 may include the headset 22 with the one or more interchangeable earloops 26 and/or earbuds 28, each interchangeable earloop 26 or earbud 28 may be of a different size, shape or configuration. In addition, the various components of the headset charging system 20 may include the headset charge pocket 30 and various interchangeable charge devices that may be coupled to the headset charge pocket 30 such as one or more interchangeable charge converter devices 40, each for charging the headset via a corresponding AC or DC adapter, and one or more interchangeable battery charge devices 42, each for charging the headset via one or more corresponding batteries.

As yet another example, FIG. 9 is a perspective view of another kit 60 that includes a mobile phone 62, an AC and/or DC adapter 64 for the mobile phone, a headset 22, and a headset charge pocket 30 with at least one interchangeable charge device for use with the mobile phone AC or DC adapter. Where both an AC and DC adapters are provided for the mobile phone 62, for example, the kit 60 may include two interchangeable charge devices 40, each configured to cooperate with one of the adapter. In addition, one or more interchangeable battery charge devices (not shown) may also be included with the kit 60.

It is noted that the charging system may also include various features such as a vibrate ring feature, a caller ID display, and/or a visual ring indicator. Each feature may be directly integrated in the headset charge pocket, integrated in another component of the charging system, and/or be provided on the headset itself but is accessible and/or visible while the headset is stored in the headset charge pocket. It is further noted that while the charging system with interchangeable charge devices is suitable for charging a headset, the system may be similarly adapted for use with any electronics devices or components that requires periodic recharging. For example, instead of providing an interchangeable headset charging system so that the headset may be recharged using the mobile telephone AC or DC adapter, an interchangeable mobile telephone charging system may be provided instead so that the mobile telephone may be recharged using the headset AC or DC adapter via a corresponding interchangeable charge device coupled to the charger. Various other applications may be similarly adapted for personal digital devices, digital cameras, video cameras, etc.

While the exemplary embodiments of the present invention are described and illustrated herein, it will be appreciated that they are merely illustrative and that modifications can be made to these embodiments without departing from the spirit and scope of the invention. Thus, the scope of the invention is intended to be defined only in terms of the following claims as may be amended, with each claim being expressly incorporated into this Description of Specific Embodiments as an embodiment of the invention.

What is claimed is:

1. An headset charging system, comprising:
a headset charger having internal electrical contacts configured to facilitate charging a headset in electrical communication with the headset charger, the headset charger being configured to be coupled to a plurality of differently configured interchangeable charging devices; and
at least one of the plurality of the differently configured interchangeable charging devices configured to be repeatedly coupled to and uncoupled from the headset charger, the at least one interchangeable charging device being further configured to facilitate charging of the headset via a charge source in electrical communication with the interchangeable charging device.

2. The system of claim 1, wherein the charge source is selected from the group consisting of an AC adapter, a DC adapter, and at least one battery.

3. The system of claim 1, wherein the headset charger is further configured to be directly coupled to at least one of a headset charger AC adapter and a headset charger DC adapter when the at least one interchangeable charging device is uncoupled from the headset charger.

4. The system of claim 1, wherein the headset charger is a headset charge pocket configured to receive the headset therein.

5. The system of claim 1, wherein the headset charger includes at least one of a vibrate ring feature, a caller ID display, and a visual ring indicator.

6. The system of claim 1, comprising a plurality of the interchangeable charging devices, at least one of the interchangeable charging devices is a battery charge device configured to contain at least one battery therein for charging the headset.

7. The system of claim 1, wherein the at least one interchangeable charging device is a battery charge device configured to contain at least one battery therein for charging the headset, each battery being selected from the group consisting of an alkaline battery, a NiCad battery and a lithium battery.

8. The system of claim 1, wherein the at least one interchangeable charging device is a charge converter device configured to be coupled to one of an AC adapter and a DC adapter.

9. The system of claim 8, wherein the headset charger is further configured to be directly coupled to at least one of a headset charger AC adapter and a headset charger DC adapter when the at least one interchangeable charging device is uncoupled from the headset charger.

10. The system of claim 1, wherein the at least one interchangeable charging device is further configured to be repeatedly coupled to and uncoupled from another interchangeable charging device.

11. The system of claim 1, further comprising the headset.

12. A charging system, comprising:
an apparatus charger having internal electrical contacts configured to facilitate charging an electronics apparatus in electrical communication with the charger, the apparatus charger being configured to be coupled to a plurality of differently configured interchangeable charging devices; and
at least one of the plurality of differently configured interchangeable charging devices configured to be repeatedly coupled to and uncoupled from the apparatus charger, the at least one interchangeable charging device being further configured to facilitate charging of the electronics apparatus via a charge source in electrical communication with the at least one interchangeable charging device.

13. The charging system of claim 12, wherein the apparatus charger is further configured to be directly coupled to at least one of a device charger AC adapter and a device charger DC adapter when the at least one interchangeable charging device is uncoupled from the apparatus charger.

14. The charging system of claim 12, wherein the apparatus charger is configured to receive a headset therein, the apparatus charger providing at least one of a vibrate ring feature, a caller ID display, and a visual ring indicator.

15. The charging system of claim 12, comprising a plurality of the interchangeable charging devices, at least one of the interchangeable charging devices is a battery charge device configured to contain at least one battery therein for charging the electronics device.

16. The charging system of claim 1, wherein the at least one interchangeable charging device is further configured to be repeatedly coupled to and uncoupled from another interchangeable charging device.

17. A kit, comprising:
a mobile telephone;
a headset configured to be coupled to the mobile telephone;
one of an AC and DC mobile telephone adapter configured to be in electrical communication with the mobile telephone for charging the mobile telephone;
a headset charger having internal electrical contacts to facilitate charging the headset, the headset charger being configured to be coupled to a plurality of differently configured interchangeable charging devices; and
a first interchangeable charging device configured to be repeatedly coupled to and uncoupled from the headset charger, the first interchangeable charging device being further configured to be coupled to the mobile telephone adapter to facilitate charging of the headset.

18. The kit of claim 17, further comprising one of an AC and DC headset telephone adapter configured to be coupled directly to the headset charger to facilitate charging of the headset when the first interchangeable charging device is uncoupled from the headset charger.

19. The kit of claim 17, wherein the headset charger is a headset charge pocket configured to receive the headset therein.

20. The kit of claim 17, wherein the headset charger provides at least one of a vibrate ring feature, a caller ID display, and a visual ring indicator.

21. The kit of claim 17, further comprising a second interchangeable charging device that is a battery charge device configured to contain at least one battery therein to facilitate charging the headset.

22. The kit of claim 21, wherein each battery is selected from the group consisting of an alkaline battery, a NiCad battery and a lithium battery.

23. The kit of claim 17, further comprising a second interchangeable charging device, the second interchangeable charging device is further configured to be repeatedly coupled to and uncoupled from the first interchangeable charging device.
